(19) United States
(12) Patent Application Publication
(10) Pub. No.: US 2008/0032471 A1
(43) Pub. Date: Feb. 7, 2008

(54) Methods for forming shallow trench isolation structures in deep trenches and uses of the same

(75) Inventors: Wen-Shuo Kuo, Taichung City (TW); Chao-Hsi Chung, Jhubei City (TW); Yung Yao Lee, Yongkang City (TW); Hui-Min Li, Jhudong Town (TW)

Correspondence Address: NIXON PEABODY LLP - PATENT GROUP, CLINTON SQUARE, P.O. BOX 31051, ROCHESTER, NY, 14603-1051, US

(73) Assignee: Promos Technologies Inc., Hsinchu (TW)

(21) Appl. No.: 11/580,807

(22) Filed: Oct. 13, 2006

(30) Foreign Application Priority Data
Aug. 3, 2006 (TW) 095128453

(51) Int. Cl. H01L 21/8242

(52) U.S. Cl. 438/243; 438/248; 438/246; 438/244

(57) ABSTRACT

A method for manufacturing a shallow trench isolation structure in a deep trench and application thereof are provided, wherein the deep trench having an upper electrode and an insulation layer on the upper electrode is formed in a substrate which has a pad insulation layer. The method comprises the following steps: forming a hard mask on the first insulation layer, doping a first portion of the hard mask, removing the undoped portion of the hard mask to expose a portion of the first insulation layer and reserve the first portion of the hard mask, removing the exposed portion of the first insulation layer to expose a portion of the upper electrode, and forming a conductive layer on the exposed portion of the upper electrode wherein a predetermined distance exists between the upper surface of the conductive layer and the pad insulation layer.

This application claims priority to Taiwan Patent Application No. 095128453 filed on Aug. 3, 2006.

### CROSS-REFERENCES TO RELATED APPLICATIONS

Not applicable.

### BACKGROUND OF THE INVENTION

1. Field of the Invention

The subject invention relates to a method for manufacturing a shallow trench isolation structure in a deep trench and an application thereof. The subject invention especially relates to the application of the method in the manufacture of a dynamic random access memory device; more specifically, relates to the application in the manufacture of a dynamic random access memory device with a deep trench capacitor.

2. Descriptions of the Related Art

As semiconductor devices are developed to keep up with deep submicron and nanometer process technology, the specification requirements needed for the miniaturization and high integration of the devices are increasingly in demand. For dynamic random access memory (“DRAM”) device structures, not only does the size need to be miniaturized, but the memory capacity also needs to be increased. Therefore, prior designs and manufacture methods for capacitors in DRAM should be changed to meet the trend development.

Based on the structure of the contained capacitor, DRAMs that are often used can be classified into two types. One type is a DRAM with a stack capacitor and the other is a DRAM with a deep trench capacitor. According to the aforementioned trends, no matter the type of DRAM, there are continually more difficulties that are encountered in the process.

FIG. 1 depicts the top view of a schematic drawing of a deep trench capacitor array in a known DRAM with deep trench capacitors. It shows a plurality of deep trench capacitors 20 aligned on a substrate in a checkerboard pattern and strip-like active areas (“AA”) 30 located in the deep trench capacitor array. The deep trench capacitors arranged in the checkerboard pattern are to avoid short circuiting between the deep trench capacitors caused by high integration.

FIG. 2 is a sectional view according to line I-I shown in FIG. 1. In addition to a lower electrode 21, the deep trench capacitor 20 comprises a capacitor dielectric layer 23, an upper electrode 24, a collar insulation layer 25, a buried strap (“BS”) 26, and a shallow trench isolation (“STI”) 27 in a deep trench 22. The prior processes for the deep trench capacitors generally have had many problems, including the difficulty in controlling the depth of the buried strap 26 in the deep trench 22, the formation of voids in the shallow trench isolation area 27 easily, and the formation of a striated contour in the active area 30 easily. All of these problems affect the normal performance of the DRAM devices. Consequently, it is important that the prior process is improved to manufacture a DRAM device with a deep trench capacitor that deals with the continued miniaturization and high integration of the DRAM device.

### SUMMARY OF THE INVENTION

One object of the subject invention is to provide a method for manufacturing a shallow trench isolation structure in a deep trench, wherein the deep trench is formed in a substrate and contains an upper electrode and a first insulation above the upper electrode, and the substrate has a pad insulation layer formed thereon. The method comprises the following steps: forming a hard mask on the first insulation layer, doping a first portion of the hard mask, removing the undoped portion of the hard mask to expose a portion of the first insulation layer and to reserve the first portion, removing the exposed portion of the first insulation layer to expose a portion of the upper electrode, and forming a conductive layer on the exposed portion of the upper electrode wherein a predetermined distance exists between the upper surface of the conductive layer and the pad insulation layer. According to the subject invention, the depth of the shallow trench isolation structure formed in the deep trench can be precisely controlled. In other words, the depth of the buried strap is effectively controlled to eliminate problems that occur in conventional technology from difficulties in measurement and control. Moreover, the subject invention can avoid undesired voids that form in the shallow trench isolation structure, and suppress the reduction of the electrical isolation effect of the shallow trench isolation structure caused by the voids.

Another object of the subject invention is to provide a method for manufacturing a semiconductor device with a deep trench capacitor. The method comprises the following steps: providing a substrate with a pad insulation layer formed thereon and a deep trench formed therein, wherein the deep trench contains an upper electrode and a first insulation layer above the upper electrode and the upper surface of the first insulation layer is under the surface of the pad insulation layer; forming a hard mask on the first insulation layer; doping a first portion of the hard mask; removing the undoped portion of the hard mask to expose a portion of the first insulation layer and reserving the first portion; removing the exposed portion of the first insulation layer to expose a portion of the upper electrode; and forming a conductive layer on the exposed portion of the upper electrode wherein a predetermined distance exists between the upper surface of the conductive layer and the pad insulation layer. According to the method disclosed in the subject invention, the pad insulation layer on the substrate will provide an even upper surface during the manufacturing procedure, and thus, will avoid the formation of a striated contour in the subsequent process of forming an active area to enhance the performance of DRAM devices.

### BRIEF DESCRIPTION OF THE DRAWINGS

FIG. 1 depicts a top view of a deep trench capacitor array in a conventional DRAM.

FIG. 2 depicts a sectional view of line I-I shown in FIG. 1.

FIGS. 3A to 3C depict schematic drawings of the formation of an uneven pad insulation layer in the process.

FIGS. 4A to 4I depict schematic drawings of one embodiment of the formation of a shallow trench isolation structure in a deep trench according to the subject invention.

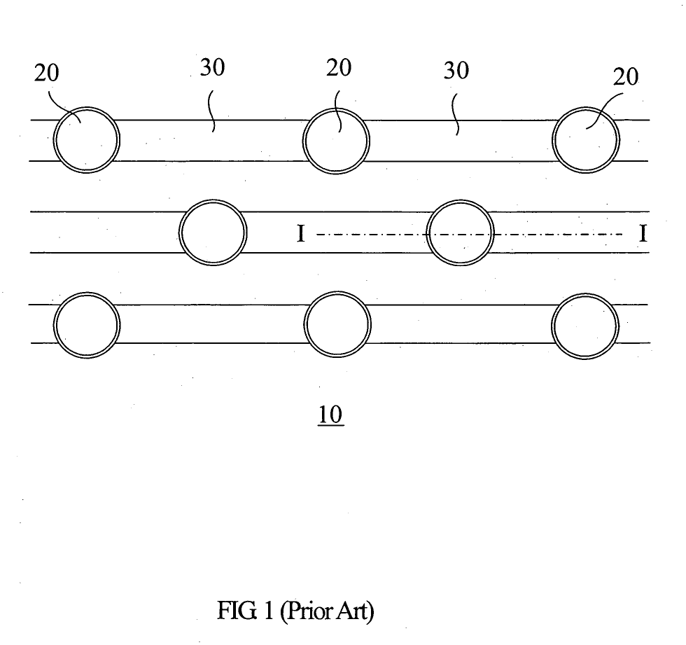

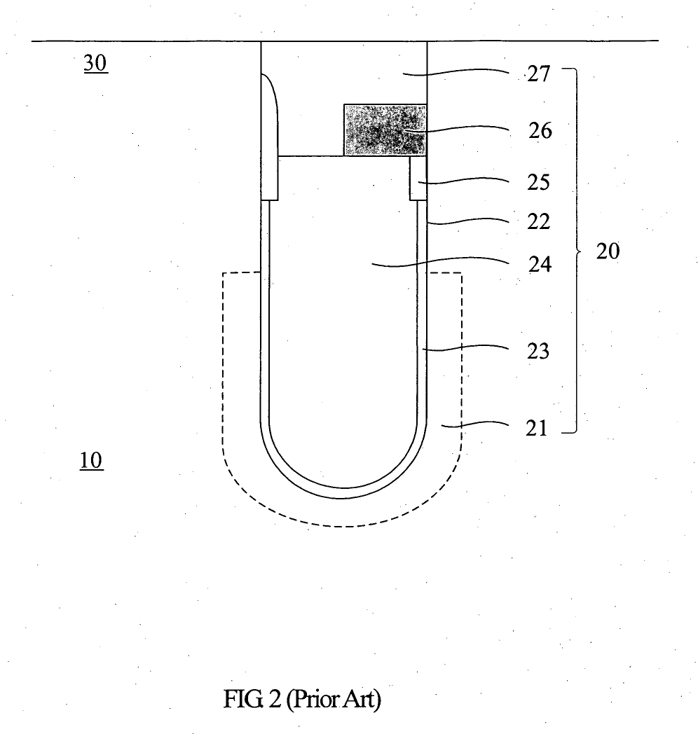

### DESCRIPTION OF THE PREFERRED EMBODIMENT

After studying conventional methods used for manufacturing deep trench capacitors, the inventors found that the above problems are a result of the uneven surface of the pad insulation layer on the substrate during the manufacturing procedures. The uneven surface is formed due to the improper etching during the manufacture. The uneven surface of the pad insulation layer cannot provide a horizontal level with a fixed height when the depth of the buried strap in the deep trench capacitor structure is measured in the manufacture. Thus, the depth of the buried strap formed in the deep trench capacitor structure cannot be easily controlled.

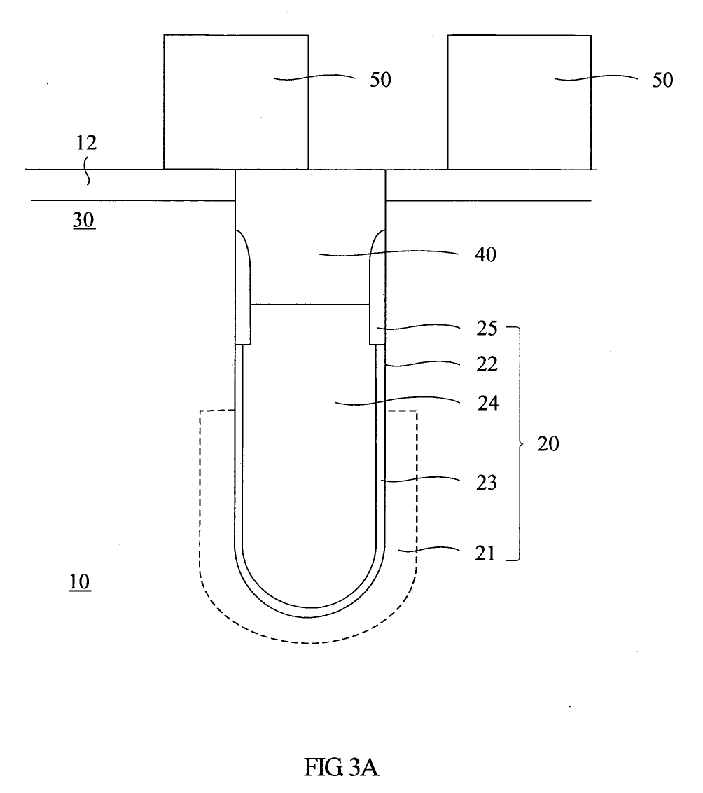

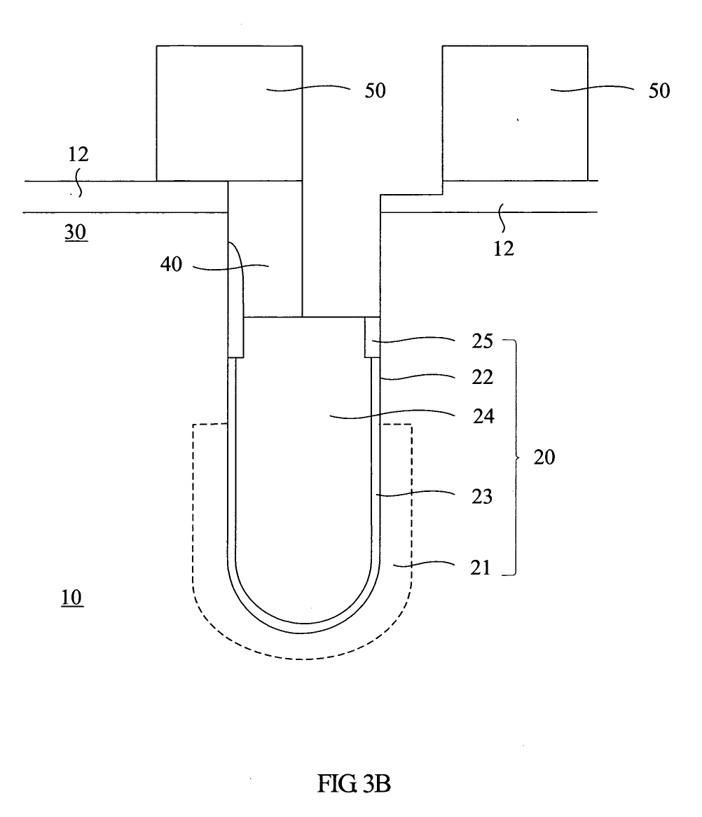

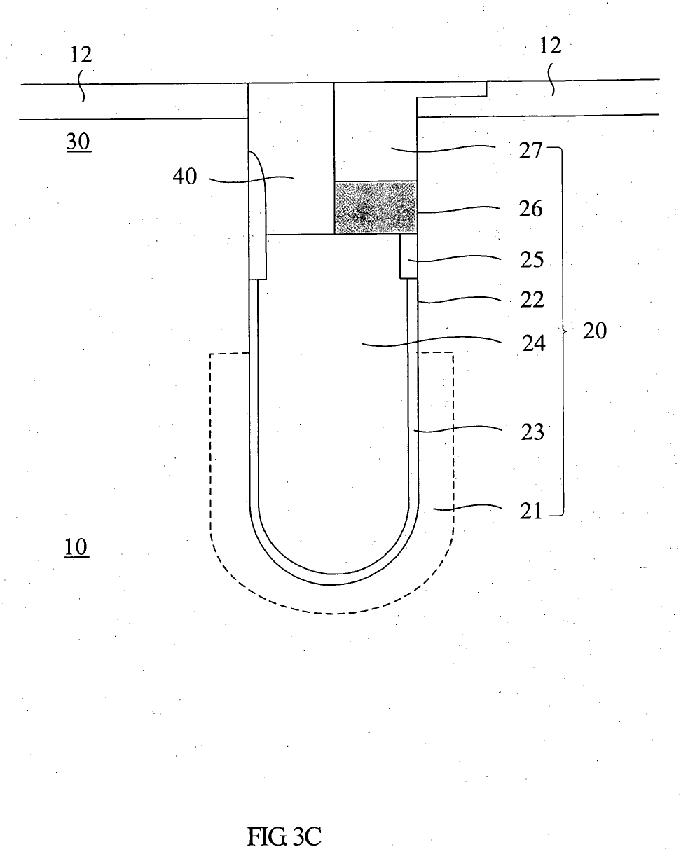

Below, relevant drawings are provided to illustrate the reasons for the formation of the aforementioned uneven surface of the pad insulation layer. Please first refer to FIG. 3A, which shows a pad insulation layer 12 formed on a substrate 10 and a deep trench capacitor 20 with a preliminary configuration and located in the interior of the substrate 10. In addition to a lower electrode 21, the deep trench capacitor 20 comprises a capacitor dielectric layer 23, an upper electrode 24, and a collar insulation layer 25 in a deep trench 22. Moreover, a first insulation layer 40 is present in the space surrounded by the upper electrode 24 and the collar insulation layer 25, and fills the deep trench 22 up to a horizontal level the same as that of the pad insulation layer 12.

With further reference to FIG. 3A, a patterned photoresist 50 is formed on the pad insulation layer 12 to expose a portion of the first insulation layer 40 at the opening of the deep trench 22. Then, referring to FIG. 3B, the patterned photoresist 50 is used as the mask during anisotropic etching to remove the exposed portion of the first insulation layer 40 and a portion of the collar insulation layer 25 on the sidewall of the deep trench 22 so as to expose a portion of the surface of the upper electrode 24. The pad insulation layer 12 is usually composed of silicon nitride, while the first insulation layer 40 is composed of silicon dioxide. However, because the selectivity of the etching rate of the silicon nitride layer to that of the silicon dioxide layer is not high, etching the first insulation layer 40 simultaneously will remove a portion of the pad insulation layer 12 exposed on the outside of the patterned photoresist 50 to form a stepped pad insulation layer 12 as shown in FIG. 3B.

Then, with reference to FIG. 3C, after removing the photoresist 50 and filling the deep trench 22 with a conductive material, the first insulation layer 40 remaining in the deep trench 22 is used as the mask for anisotropic etching to remove a portion of the conductive material to a predetermined depth so as to form a buried strap 26. Finally, a suitable insulation material is filled to form a shallow trench isolation 27 in the deep trench 22. During the removal of the conductive material by etching to form the buried strap 26, the pad insulation layer 12 has a stepped structure. Because the step height cannot be predicted, a measurement datum with a fix horizontal level cannot be provided when measuring the depth of the buried strap 26. As a result, the depth of the buried strap 26 is not easily controlled.

Furthermore, the surface of the stepped pad insulation layer is also another reason why striated contours and voids easily form in the active areas and shallow trench isolation areas, respectively, Moreover, in practicality, the apparatus per se used for manufacturing a semiconductor wafer has a non-homogenization problem. That is, the treatment effects of the center and peripheral area of the wafer are not identical in the same process step. The abovementioned surface of the stepped pad insulation layer deteriorates the non-homogenization problem, which leads to the decrease in the process yield. Based on the above finding, the subject invention provides a concrete manner that prevents the formation of the uneven surface of the pad insulation layer so as to enhance the performance of the DRAM device.

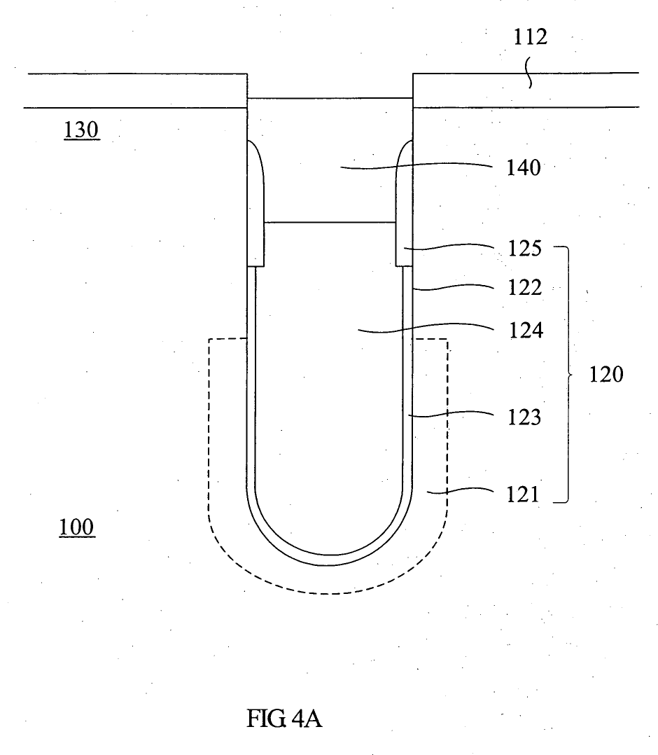

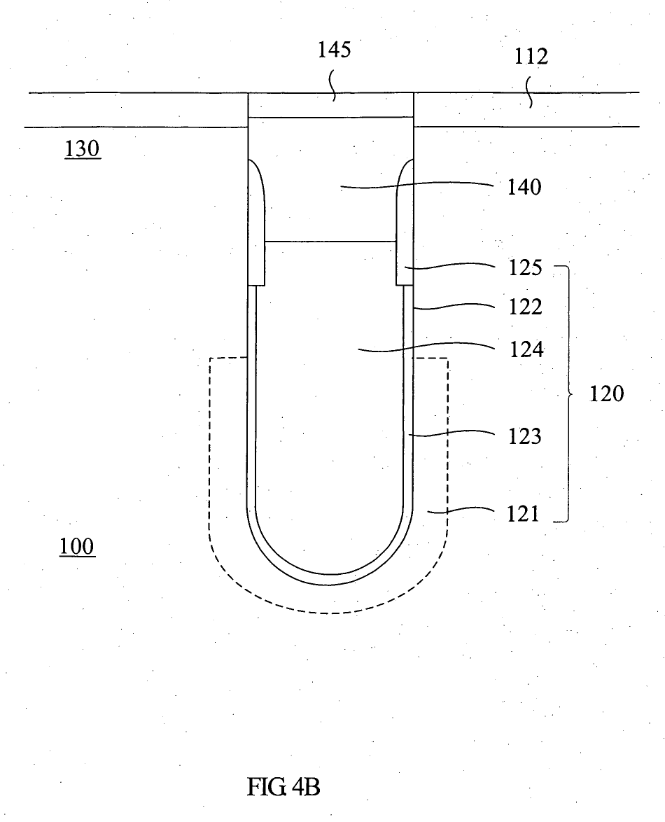

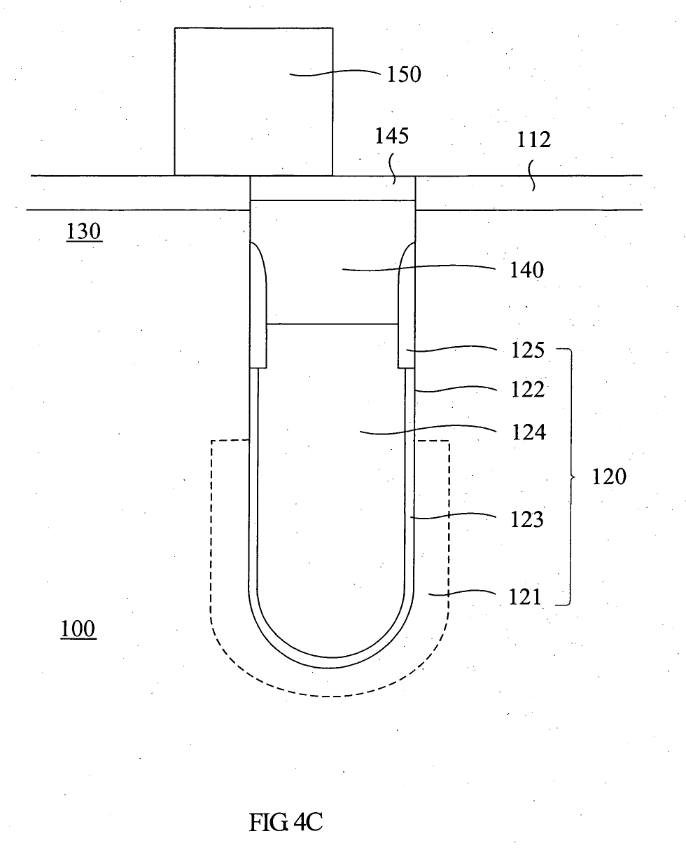

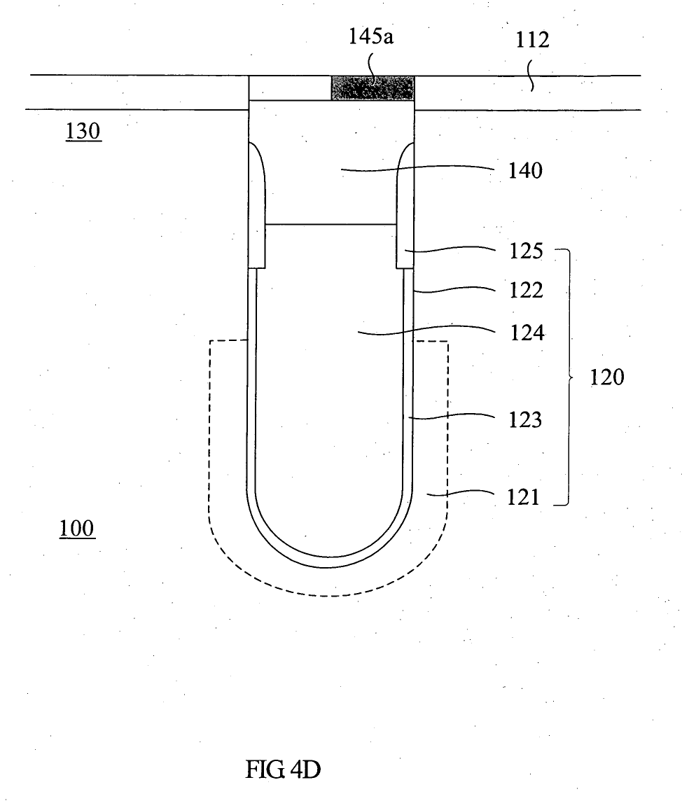

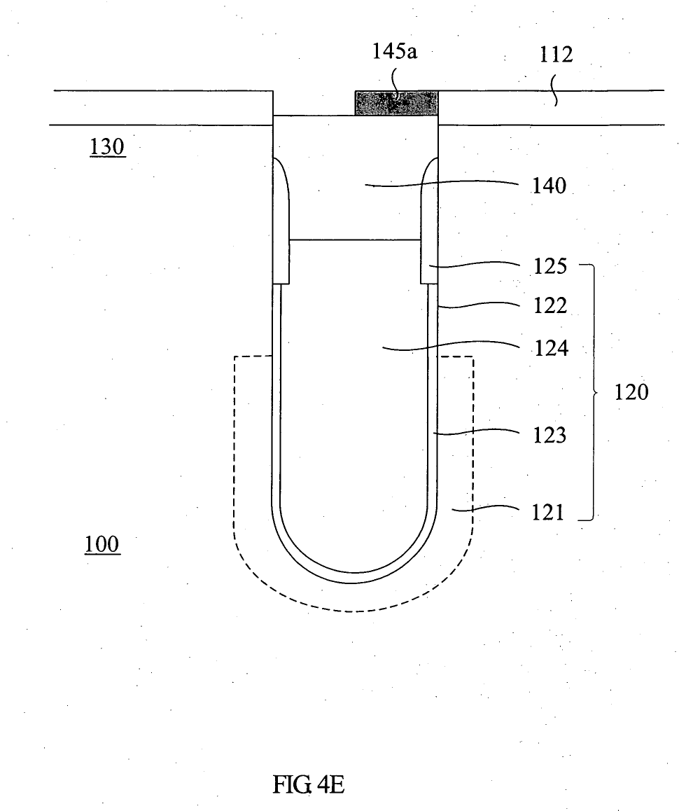

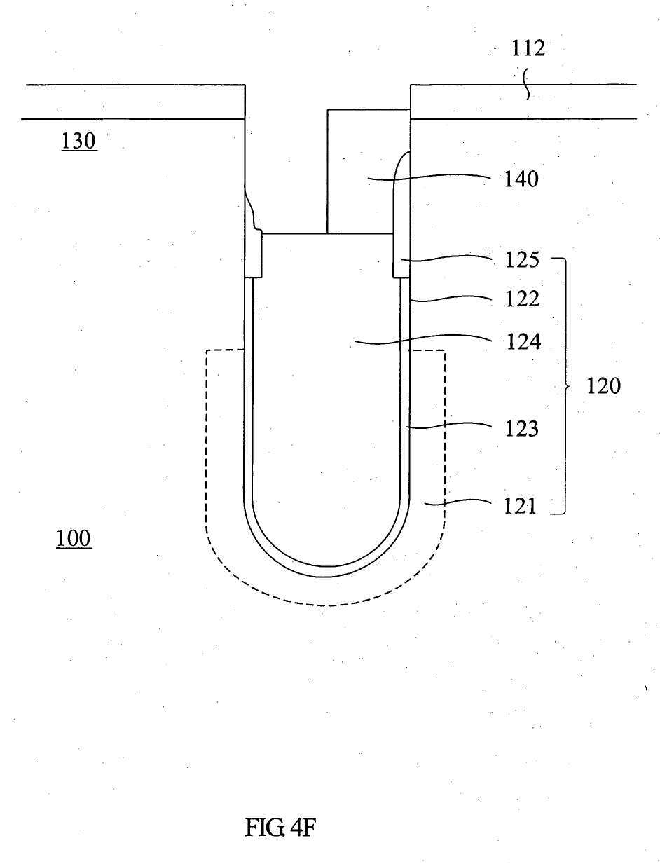

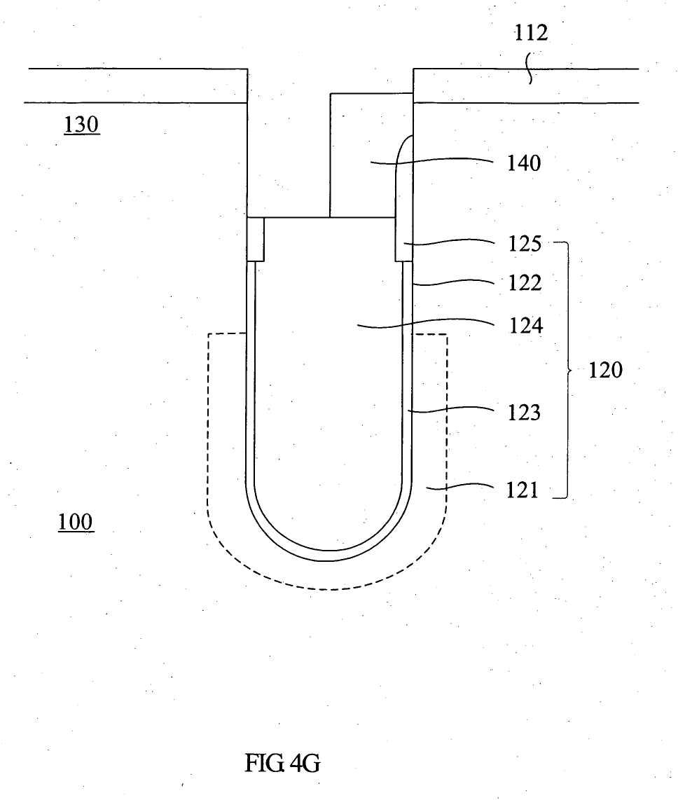

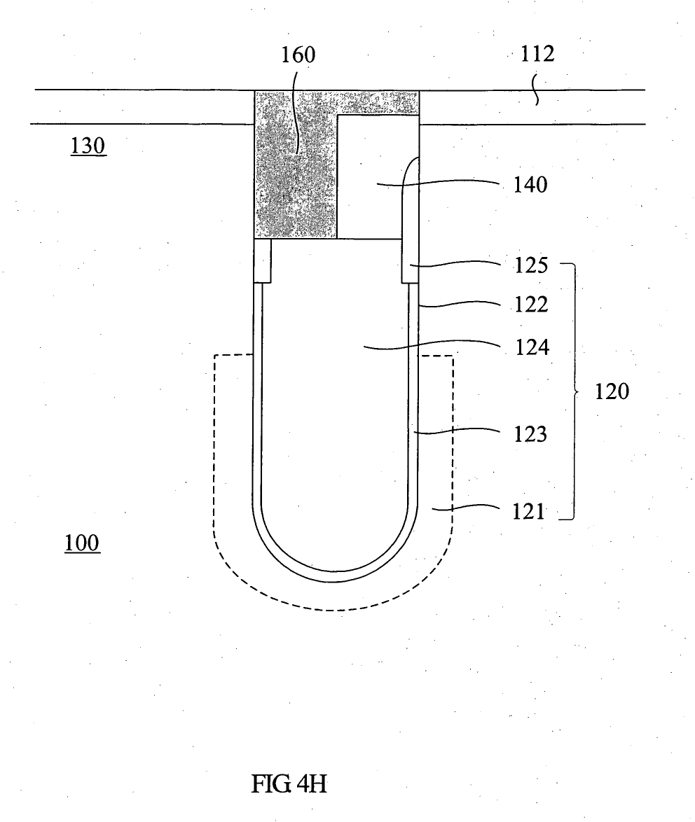

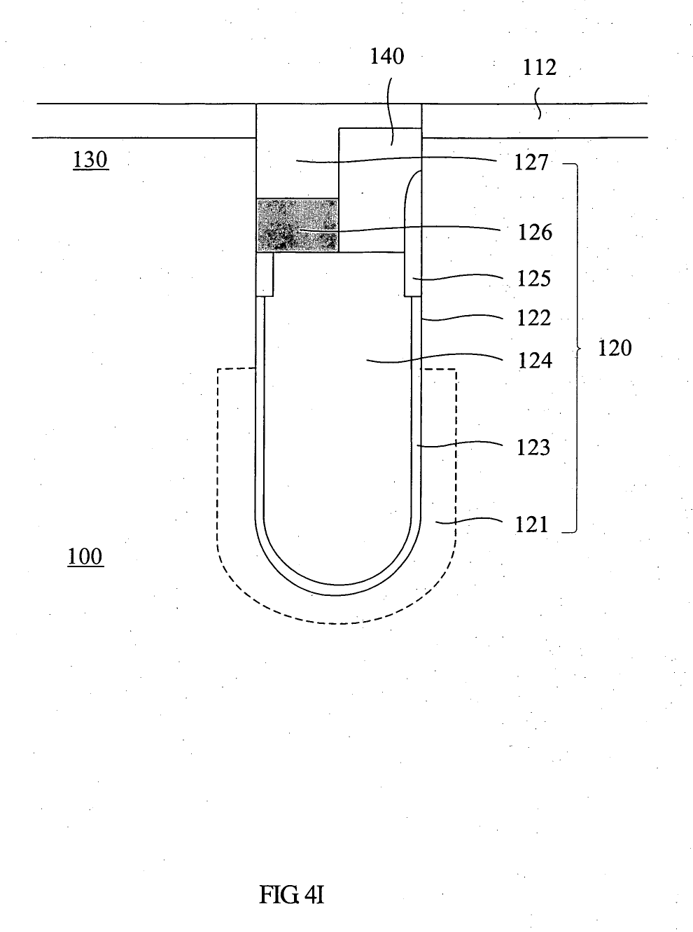

FIGS. 4A to 4I illustrate one embodiment of providing an even surface of the pad insulation layer during the fabrication of a DRAM device according to the subject invention. First, FIG. 4A depicts a sectional view of one row of the checkerboard-patterned deep trench capacitor array in a DRAM device. It shows a substrate 100, a pad insulation layer 112 on the substrate 100, a deep trench capacitor 120 inside the substrate 100, and active areas 130 between the deep trench capacitors 120 and on the substrate 100. In addition to a lower electrode 121, the deep trench capacitor 120 comprises a capacitor dielectric layer 123, an upper electrode 124, and a collar insulation layer 125 in a deep trench 122. The selection and variation of the material of each part are similar to those used in the prior art and are not further described in details.

Please further refer to FIG. 4A. A first insulation layer 140 is formed in the space that is surrounded by the upper electrode 124 and the collar insulation layer 125 and in the deep trench 122. Preferably, the first insulation layer 140 is a high density plasma silicon dioxide layer formed by using the high density plasma method. It should be mentioned that in the method of the subject invention, the upper surface of the first insulation layer 140 is not of the same level as that of the pad insulation layer 112, but that a proper space remains for use in the subsequent process. Referring to FIG. 4B, a hard mask 145 is formed on the first insulation layer 140 to fill the space remaining between the opening of the deep trench 122 and the upper surface of the first insulation layer 140. The hard mask 145 can be a polysilicon layer formed by such as chemical vapor deposition.

Then, as shown in FIG. 4C, a patterned photoresist 150 is formed to properly cover a portion of the opening of the deep trench 122 to expose a portion of the hard mask 145 located under the opening of the deep trench 122. Thereafter, with reference to FIG. 4D, the patterned photoresist 150 is first used as a mask for doping the exposed hard mask 145 as to form a doped first portion 145a. The patterned photoresist 150 is then removed. Afterward, as shown in FIG. 4E, the undoped portion of the hard mask 145 is removed to expose a portion of the first insulation layer and remain the first portion 145a.

Any suitable manner can be utilized to provide the first portion 145a. The only requirement is that the selectivity of etching rate of the first portion 145a and that of the undoped portion of the hard mask 145 is up to 1:5 or higher. For example, if the polysilicon is used to provide the hard mask 145, the hard mask 145 can be doped with boron to form a boron-doped first portion 145a. Thereafter, by utilizing the high etching selectivity between the undoped polysilicon and the boron-doped polysilicon in diluted ammonia (“DAM”), DAM is used to remove the undoped portion of the hard mask 145. In practicality, the boron ion beam with an energy ranging from about 10 to 200 KeV and a concentration ranging from 10¹² to 10¹⁵ cm⁻² is used to conduct the boron doping in an ion implantation manner. Preferably, the boron ion beam is BF²⁺, with an energy ranging from 10 to 50 KeV and a concentration ranging from 10¹⁴ to 10¹⁵ cm⁻².

Then, with reference to FIG. 4F, the doped first portion 145a is used as the mask to remove the exposed first insulation layer 140 which is not covered by the first portion 145a, as well as a portion of the collar insulation layer 125 located on the upper surface of the upper electrode 124 and the sidewall of the deep trench 122, so as to expose a portion of the upper electrode 124 located under the first insulation layer 140. An anisotropic etch can be utilized to remove the first insulation layer 140 and the collar insulation layer 125. In this aspect, when the anisotropic etch is conducted, although the pad insulation layer 112 on the substrate 100 is also exposed to the etching environment and is subjected to anisotropic etching, the etching substantially and homogeneously applies to the whole pad insulation layer 112. Therefore, the thickness of the pad insulation layer 112 will be uniformly reduced and kept at the same level; thus, there would be no stepped or uneven surface resulting, After the first insulation layer 140 and the collar insulation layer 125 are partially removed, the first portion 145a is removed.

Please refer to FIG. 4G. The first insulation layer 140 and the collar insulation layer 125 remaining on the sidewall of the deep trench 122 are optionally removed. For example, a diluted hydrofluoric acid (“DHF”) or buffer hydrofluoric acid (“BHF”) is used as a wet etchant to conduct an isotropic etch so as to thoroughly clean the residues on the sidewall of the deep trench 122. Given the above, the method of the subject invention can provide a space for manufacturing the buried strap and the shallow trench isolation so that the pad insulation layer does not have an uneven surface.

Thereafter, please refer to FIG. 4H. In the deep trench 122, a conductive layer 160 is formed on the exposed upper layer 124. Generally, the material of the conductive layer 160 is the same as that of the upper electrode 124 and is usually made of a polysilicon layer, preferably made of a doped polysilicon layer with a better conductive property, such as an arsenic-doped polysilicon layer. Then, the portion of the conductive layer 160 that is higher than the upper surface of the pad insulation layer 112 is optionally removed by chemical mechanical publishing to allow the upper surface of the conductive layer 160 to be in the same level as that of the pad insulation layer.

In the above embodiment, because the first portion 145a is first removed, the conductive layer 160 will also fill the space of the first portion 145a as shown in FIG. 4E. However, if the hard mask 145 utilizes the polysilicon material as described above, then the first portion 145a does not need to be removed. In this case, it is possible that an eaves-like structure may form during the removal of the insulation material remaining on the sidewall of the deep trench by isotropic etching, because the first insulation layer 140 below the first portion 145a is partially etched away. The eaves-like structure is unfavorable to the subsequent formation of the conductive layer 160. Therefore, according to the subject invention, it is preferred for the first portion 145a to be removed.

Finally, in reference to FIG. 4I, a portion of the conductive layer 160 in the deep trench 122 is removed to allow a predetermined distance to exist between the upper surface of the conductive layer 160 and the opening of the deep trench 122 in order to manufacture the buried strap 126 in the deep trench capacitor of a DRAM device. Then, an insulation material is used to fill the space between the upper surface of the buried strap 126 and the opening of the deep trench 122 to form a small shallow trench isolation 127 in the deep trench capacitor. Any suitable manner can be used to fill the insulation material. For example, a high density method can be used to form a high density plasma silicon dioxide as the insulation material.

According to the manufacturing method disclosed in the subject invention, the upper surface of the pad insulation layer 112 formed in the process is flat. Consequently, any problems possibly caused from the uneven pad insulation layer 112 are avoided. Moreover, since the pad insulation layer 112 has an even surface, voids cannot easily form like they did in the prior technology. In addition, there is no undesired filling of the conductive material in the voids during subsequent processes, which prevents short circuiting between the capacitor and the gate electrode and/or between the gate electrode and the gate electrode.

The above examples are only intended to illustrate the principle and efficacy of the subject invention, not to limit the subject invention. Any people skilled in this field may proceed with modifications and changes to the above examples without departing from the technical principle and spirit of the subject invention. Therefore, the scope of protection of the subject invention is covered in the following claims as appended.

What is claimed is:

1. A method for manufacturing a shallow trench isolation structure in a deep trench, wherein the deep trench is formed in a substrate and contains an upper electrode and a first insulation layer above the upper electrode, and the substrate has a pad insulation layer formed thereon, which method comprises:
forming a hard mask on the first insulation layer;
doping a first portion of the hard mask;
removing the undoped portion of the hard mask to expose a portion of the first insulation layer and to reserve the first portion;
removing the exposed portion of the first insulation layer to expose a portion of the upper electrode; and
forming a conductive layer on the exposed portion of the upper electrode, wherein a predetermined distance exists between the upper surface of the conductive layer and the surface of the pad insulation layer.

2. The method of claim 1, wherein the pad insulation layer is a silicon nitride layer.

3. The method of claim 1, wherein the hard mask is a polysilicon layer.

4. The method of claim 1, wherein the hard mask is implanted by boron ions.

5. The method of claim 1, wherein the first insulation layer is a silicon dioxide layer.

6. The method of claim 1, wherein the deep trench further contains a collar insulation layer on the sidewall and the steps of removing the exposed portion of the first insulation layer comprises:
using the first portion as a mask to anisotropically etch the first insulation layer and the collar insulation layer to expose a portion of the upper electrode; and
isotropically etching to remove the first insulation layer and the color insulation layer remained on the sidewall of the deep trench.

7. The method of claim 1, wherein the first portion is removed before the formation of the conductive layer.

8. The method of claim 1, wherein the steps of forming the conductive layer comprises:
filling the deep trench with a conductive material; and
removing a portion of the conductive material to form a predetermined distance from the upper surface of the layer composed by the conductive material to the surface of the pad insulation layer.

9. The method of claim 1, wherein the conductive layer is a doped polysilicon layer.

10. The method of claim 1, further comprising forming a second insulation layer in the deep trench and above the conductive layer.

11. A method for manufacturing a semiconductor device having a deep trench capacitor, comprising:
providing a substrate having a pad insulation layer formed thereon and a deep trench formed therein, wherein the deep trench contains an upper electrode and a first insulation layer above the upper electrode and the surface of the first insulation layer is lower than the surface of the pad insulation layer;
forming a hard mask on the first insulation layer;
doping a first portion of the hard mask;
removing the undoped portion of the hard mask to expose a portion of the first insulation layer and to reserve the first portion;
removing the exposed portion of the first insulation layer to expose a portion of the upper electrode; and
forming a conductive layer on the exposed portion of the upper electrode, wherein a predetermined distance exists between the upper surface of the conductive layer and the surface of the pad insulation layer.

12. The method of claim 11, wherein the pad insulation layer is a silicon nitride layer.

13. The method of claim 11, wherein the hard mask is a polysilicon layer.

14. The method of claim 11, wherein the step of doping the hard mask is to implant boron ions.

15. The method of claim 11, wherein the first insulation layer is a silicon dioxide layer.

16. The method of claim 11, wherein the deep trench further contains a collar insulation layer on the sidewall and the step of removing the exposed portion of the first insulation layer comprises:
using the first portion as a mask to anisotropically etch the first insulation layer and the collar insulation layer to expose a portion of the upper electrode; and
isotropically etching to remove the first insulation layer and the color insulation layer remained on the sidewall of the deep trench.

17. The method of claim 11, wherein the first portion is removed before the formation of the conductive layer.

18. The method of claim 11, wherein the step of forming the conductive layer comprises:
filling the deep trench with a conductive material; and
removing a portion of the conductive material to form a predetermined distance from the upper surface of the layer composed by the conductive material to the surface of the pad insulation layer.

19. The method of claim 11, wherein the conductive layer is a doped polysilicon layer.

20. The method of claim 11, further comprising forming a second insulation layer in the deep trench and above the conductive layer.
